(19) United States
(12) Patent Application Publication
(10) Pub. No.: US 2026/0287643 A1
(43) Pub. Date: Sep. 24, 2026

(54) SEMICONDUCTOR SOCKET

(71) Applicant: United Precision Technologies Co., Ltd., Tokyo (JP)

(72) Inventors: Shinji YAMADA, Tokyo (JP); Hideki SATO, Tokyo (JP)

(73) Assignee: United Precision Technologies Co., Ltd., Tokyo (JP)

(21) Appl. No.: 19/473,486

(22) PCT Filed: Mar. 19, 2024
(86) PCT No.: PCT/JP2024/010840

§ 371 Date: Oct. 8, 2025

(30) Foreign Application Priority Data
Apr. 13, 2023 (JP) 2023-065424

(51) Int. Cl. G01R 31/28

(52) U.S. Cl. CPC G01R 31/2863

(57) ABSTRACT

To smoothly perform precise alignment between the contacts of a semiconductor package and the contact pieces. In a semiconductor socket for positioning each solder ball arranged in a rectangular parallelepiped-shaped semiconductor package and each corresponding contact piece arranged in a state of being electrically insulated from each other, a through-hole is formed having a guide portion for guiding the semiconductor package into the guide body from the arrangement surface of the solder balls, and a housing portion for accommodating the semiconductor package guided by the guide portions, and the guide portions, include a tapered portion facing each side edge of the arrangement surface and becoming narrower toward the guiding direction of the semiconductor package and a clearance portion facing each corner portion of the arrangement surface.

### FIELD OF THE INVENTION

The present invention relates to a semiconductor socket, and more particularly to a semiconductor socket for positioning each contact arranged in a semiconductor package in a rectangular parallelepiped-shape and each corresponding contact piece arranged in a state of being electrically insulated from each other.

### BACKGROUND OF THE INVENTION

Patent Document 1 discloses a test socket that connects a semiconductor device to a circuit board constituting a test circuit or an actual circuit and performs testing. Referring to FIG. 1 of Patent Document 1, a recess (19) for mounting a semiconductor device (10) is formed on an upper surface of a test socket (16). The semiconductor device (10) connects electrodes on a lower surface of its interposer substrate (12) to contact probes (20) of the test socket (16).

### PRIOR ART DOCUMENT

### Patent Document

Patent Document 1: Japanese Unexamined Patent Application Publication No. 2006-250901

### SUMMARY OF THE INVENTION

### Problems to be Solved by the Invention

As a matter of technical common sense, the test socket disclosed in Patent Document 1, when testing a semiconductor device, is considered to naturally perform alignment in order to connect the electrodes on a lower surface of the interposer substrate (12) to contact probes (20) of the test socket (16); however, since alignment is not regarded as a problem to be solved, details of how alignment is performed are not described.

As far as can be seen from FIG. 1 of Patent Document 1, when the semiconductor device rotates about its axis (vertical direction in the FIG. 1), the semiconductor device (10) may not be smoothly mounted in the recess (19), or even if mounted, precise positioning may not be achieved.

However, it can be presumed that the test socket described in Patent Document 1 also achieves reasonably precise positioning; however, since the miniaturization of semiconductor devices has progressed further compared with the time when the invention described in Patent Document 1 was made, it is necessary to devise the shape and other aspects of the test socket in order to maintain test throughput.

Accordingly, in view of such circumstances, the present invention has as its object to make it possible to smoothly achieve precise alignment between the contacts of a semiconductor package (corresponding to electrodes of a semiconductor device) and the contact pieces (corresponding to contact pins).

### Means to Solve the Problem

In order to solve the above problems, in a semiconductor socket, for positioning each contact arranged in a semiconductor package in a rectangular parallelepiped shape and each corresponding contact piece arranged in a state of being electrically insulated from each other, the present invention includes a through-hole including a guide portion for guiding the semiconductor package into a guide body from an arrangement surface of each contact arranged in the semiconductor package and a housing portion for accommodating the semiconductor package guided by the guide portion, wherein the guide portion includes a tapered portion that faces each edge portion of the arrangement surface and becomes narrower toward a guiding direction of the semiconductor package and a clearance portion that faces each corner portion of the arrangement surface.

Further, the through-hole may be formed in a guide located between a contact unit having the respective contact pieces and a push plate that presses the semiconductor package against the contact unit.

Yet further, the through-hole may be formed in a base attached to a guide located between a contact unit having the respective contact pieces and a push plate that presses the semiconductor package against the contact unit.

Furthermore, a receiving portion of the arrangement surface may be formed in the through-hole.

In addition, a package receiving sheet covering the through-hole may be included, and a receiving portion for receiving the arrangement surface may be formed in the package receiving sheet.

### BRIEF EXPLANATION OF THE DRAWINGS

FIG. 1 is an exploded perspective view of a semiconductor socket 100 according to Embodiment 1 of the present invention.

FIG. 2 is a perspective view showing the relationship among a PCB 20, a guide 40, a semiconductor package 50, and a male screw 60 shown in FIG. 1.

FIG. 3 is a plan view of the guide 40 shown in FIG. 2.

FIG. 4 is a cross-sectional view showing the relationship between the guide 40 and the semiconductor package 50 shown in FIG. 1.

FIG. 5 is a perspective view showing the relationship between the guide 40 and a base 80 attached thereto in the semiconductor socket 100 according to Embodiment 2 of the present invention.

FIG. 6 is a cross-sectional view of FIG. 5 and an enlarged view of a portion thereof.

FIG. 7 is a rear perspective view of the semiconductor package 50 shown in FIG. 6.

FIG. 8 is a perspective view showing the relationship between the guide 40 and the base 80 attached thereto in the semiconductor socket 100 according to Embodiment 3 of the present invention.

FIG. 9 is an enlarged view of the vicinity of the semiconductor package 50 shown in FIG. 8(b).

FIG. 10 is a cross-sectional view showing the relationship among the guide 40, the semiconductor package 50, the base 80, and the package receiving sheet 90 shown in FIG. 8, and an enlarged view of a portion thereof.

FIG. 11 is a rear perspective view of the semiconductor package 50 shown in FIG. 10.

### EMBODIMENTS OF THE INVENTION

Hereinafter, with reference to the drawings, a semiconductor socket 100 according to embodiments of the present invention will be described. It should be noted that the terms such as upper, lower, front, rear, obverse, and reverse used in this specification are relative terms based on the typical usage state of the semiconductor socket 100 or on the referenced drawings.

### Embodiment 1

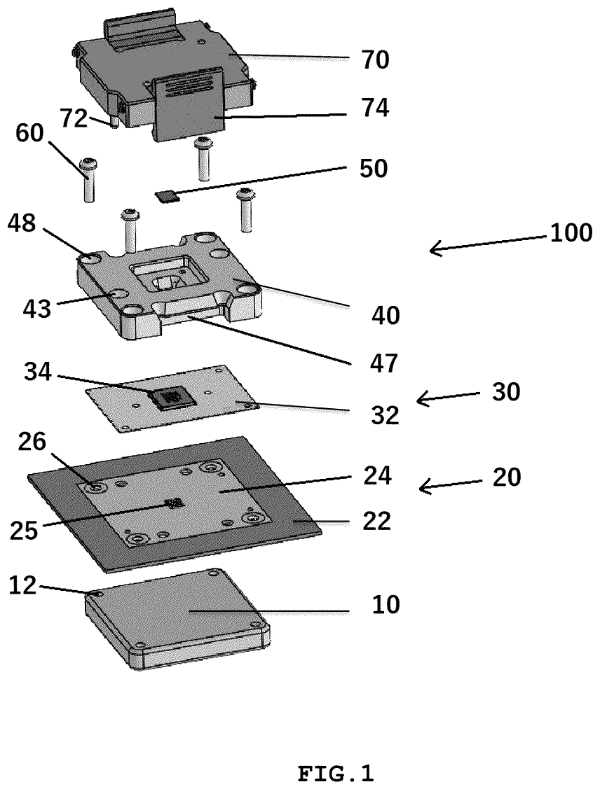

FIG. 1 is an exploded perspective view of a semiconductor socket 100 according to Embodiment 1 of the present invention. The semiconductor socket 100 is broadly divided into a bolster 10, a printed circuit board (PCB) 20, a contact unit 30, a guide 40, a semiconductor package 50, a male screw 60, and a push plate 70, which will be described below.

The bolster 10 is a member made of stainless steel or the like, which maintains the coupled state of itself, the guide 40, the PCB 20, and the contact unit 30. A female screw 12 is formed at the four corner of the bolster 10 along a vertical direction so as to be engaged with the male screw 60 in the following manner.

That is, each male screw 60 passes through a screw hole 48 formed at each of the four corners of the guide 40 along the vertical direction, and also passes through a screw hole 26 formed at each of the four corners of the PCB 20 along the vertical direction, and is then screwed into the female screw 12.

The PCB 20 is a substrate made of epoxy resin or the like, in which conductive wiring is formed on its surface and inside, as is well known. The PCB 20 is broadly divided into a resist-formed region 22 and a resist-free region 24, which will be described below.

In the resist-free region 24, electrode pads 25, in which electrodes arranged so that a plurality of contact pieces described later of the contact unit 30 independently make contact, are formed at the central portion, and screw holes 26 through which the male screws 60 pass are formed at the four corners.

In the resist-formed region 22, each wiring is formed inside so as to be electrically connected to each of the electrodes of the electrode pads 25.

The contact unit 30 includes a positioning sheet 32 and sheet-shaped contacts 34, which will be described below. A sheet-shaped contact 34 is formed by embedding a plurality of contact pieces having desired conductivity and strength two-dimensionally in such a manner that both ends thereof protrude from the front and rear surfaces of an insulating elastic body such as silicon, and by connecting them with adhesive or the like at the center of an insulating sheet (not shown).

In the insulating sheet, a through-hole corresponding to the arrangement position of the respective contact piece is provided. Therefore, the respective contact piece can pass through the corresponding through-hole and make contact with the corresponding electrode of the electrode pad 25 on the PCB 20.

The positioning sheet 32 has an opening corresponding to the insulating elastic body of the sheet-shaped contact 34 and is adhered to an upper surface of the insulating sheet via a double-sided insulating tape (not shown) or the like. The positioning sheet 32 may itself be an insulator or may be a non-insulating body at least coated with an insulating film on the through-holes and both end edges thereof.

Each contact piece of the sheet-shaped contacts 34 can be manufactured using a material having high conductivity and high strength, such as a copper alloy like copper-silver alloy or beryllium-copper alloy. In addition, at least the surfaces of both ends of the respective contact pieces may be coated with materials such as nano-silver (silver of nanoscale size) or graphene to further increase conductivity.

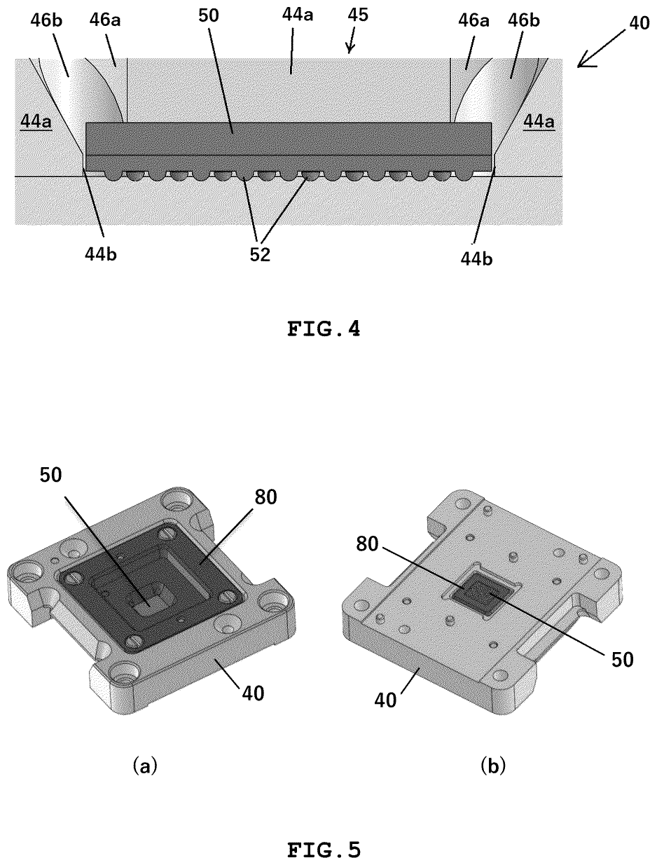

The guide 40 guides and houses the semiconductor package 50 from the arrangement surface of the contacts, such as solder balls 52 (see FIGS. 4 and 7), into the guide body, that is, toward the sheet-shaped contacts 34. The detailed structure of the guide 40 will be described later with reference to FIG. 3, but its general shape is a rectangular parallelepiped, wherein screw holes 48 as described above are formed at the four corners, on a first pair of side edges on the left and right sides of the drawings, for example, two pin receivers 43 for alignment with the push plate 70 are formed, and, on a second pair of side edges at the front and rear sides of the drawings, stopper receivers 47 for receiving stoppers 74 of the push plate 70 are formed.

The semiconductor package 50 is a semiconductor package such as a Ball Grid Array (BGA), having a semiconductor IC chip (not shown) inside. The semiconductor package 50 has a rectangular parallelepiped shape, and a plurality of contacts such as solder balls 52 are arranged on its rear surface (the surface on the side of the guide 40). These contacts, in a state accommodated in the guide 40, are brought into physical and electrical contact with the corresponding contact pieces arranged in the sheet-shaped contacts 34.

The male screw 60, as described above, passes through the screw holes 48 at the four corners of the guide 40 and the screw holes 26 at the four corners of the resist-free region 24 of the PCB 20, and is screwed into the female screw 12 at the four corners of the bolster 10.

A push plate 70 presses the semiconductor package 50 into the guide 40 and fixedly defines the position of the semiconductor package 50 mainly in the vertical direction. The push plate 70 is provided with, for example, two positioning pins 72 (one not shown) inserted into the pin receivers 43 of the guide 40, and stoppers 74 received by the stopper receivers 47 of the guide 40.

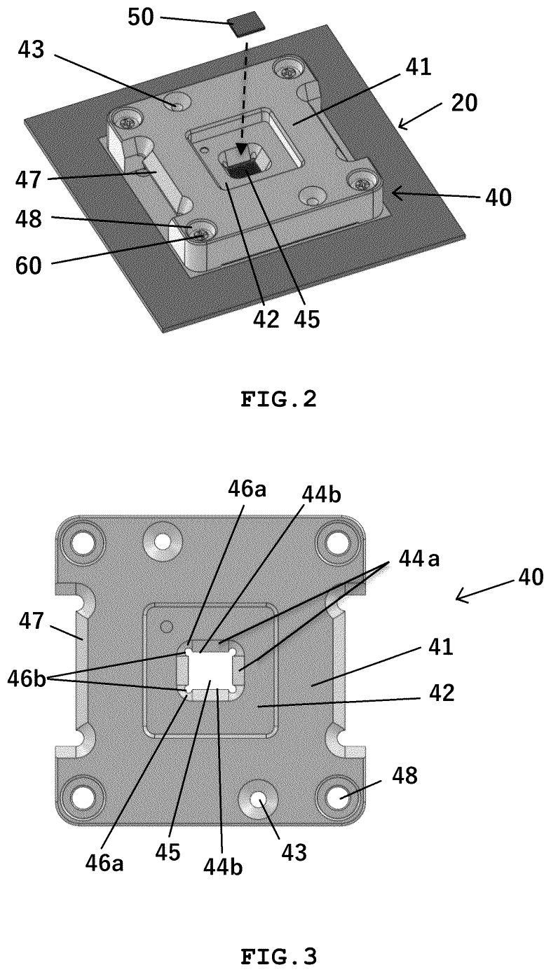

FIG. 2 is a perspective view showing the relationship among the PCB 20, the guide 40, the semiconductor package 50, and the male screws 60 shown in FIG. 1.

FIG. 3 is a plan view of the guide 40 shown in FIG. 2.

FIG. 4 is a cross-sectional view showing the relationship between the guide 40 and the semiconductor package 50 shown in FIG. 1.

As shown in FIG. 2, the guide 40 is located at the center of the surface of the PCB 20, and the PCB 20 and the guide 40 are connected by male screws 60 passing through screw holes 48 and the like.

As shown in FIGS. 2 and 3, the surface side of the guide 40 is broadly divided into a central portion 42 and a peripheral portion 41. In the peripheral portion 41, the pin receivers 43, the stopper receivers 47, and the screw holes 48 described above are formed.

In the central portion 42, a through-hole 45 for guiding and housing the semiconductor package 50 therein is formed. The guide portion or function of the through-hole 45 is mainly realized by slope portions 44a, tapered portions 46a, and cylindrical portions 46b, which will be described below, and the housing portion or function of the through-hole 45 is mainly realized by side portions 44b and cylindrical portions 46b, which will be described below.

As can be easily understood by referring to FIGS. 4 and 2, from the surface to the rear surface of the guide 40 (the guiding direction of the semiconductor package 50), each slope portion 44a has a tapered shape forming a part of a truncated square pyramid as a whole, each tapered portion 46a has a tapered shape forming a part of a truncated cone, each cylindrical portion 46b has a shape forming a part of a cylinder with a constant diameter, and each side portion 44b has a shape forming a part of four edges of a rectangular parallelepiped with a constant width.

Here, each slope portion 44a may be formed so that the distances between the first pair of opposite sides and between the second pair of opposite sides at the surface-side end portion (opening end portion) of the guide 40 are, for example, about 1.2 to 2.0 times the corresponding distances between the first and second pairs of opposite sides of the semiconductor package 50. On the other hand, the distances between the first and second pairs of opposite sides at the rear-surface-side end portion of the guide 40 (the boundary portion with the side portions 44b) may be set to the corresponding distances between the first and second pair of opposite sides of the semiconductor package 50, with an added permissible deviation amount, in order to ensure contact between the contact pieces of the sheet-shaped contacts 34 and the corresponding contacts of the semiconductor package 50.

That is, if the bottom surface of the semiconductor package 50 has a “long side length×short side length” of “A x B,” and the deviation amount is “α,” the “long side length×short side length” at the opening end portion may be, for example, “1.5A ×1.5B,” and the “long side length x short side length” at “the boundary portion with the side portions 44b” may be “(A+α)×(B+α).”

The deviation amount “a” tends to be determined, for example, by the shape and size of the contact surface of each contact piece and each contact; however, for instance, if the contact surface is square with a “long side length×short side length” of “2a×2a,” and each contact is spherical with a diameter of “2a,” then the deviation amount “α” may be “a±20%.”

When the slope portions 44a are constructed under such conditions, since the tapered portions 46a have a shape forming part of a truncated cone, and the cylindrical portions 46b have a shape forming part of a cylinder, the rectangular parallelepiped semiconductor package 50 can be guided toward the space surrounded by the side portions 44b.

Specifically, the slope portions 44a function as tapered portions facing the respective side edges of the arrangement surface of the solder balls 52 of the semiconductor package 50, the tapered portions 46a function as tapered portions facing the respective corners of the arrangement surface of the solder balls 52 of the semiconductor package 50, and the cylindrical portions 46b function as clearance portions facing the corners of the arrangement surface of the solder balls 52 of the semiconductor package 50.

In addition, by providing several parallel ribs extending from the surface side portion of the guide 40 toward the rear surface side portion on at least the central part of the surface of the slope portions 44a, the contact area may be reduced, thereby further improving the guiding efficiency of the semiconductor package 50.

Furthermore, it is not essential that the tapered portions 46a have a shape forming a part of a truncated cone, and they may instead have a shape forming a part of a truncated pyramid whose virtual base diameter is larger than that of the truncated square pyramid of the slope portions 44a, for example. Also, it is not essential that the cylindrical portions 46b have a shape forming a part of a cylinder, and they may instead have a shape forming a part of the same truncated cone as the tapered portions 46a, for example.

Returning to FIG. 2, the central portion 42 of the guide 40 is formed at a recessed position relative to the peripheral portion 41. This is because a mounting member is resiliently attached to the rear surface of the push plate 70, the mounting member having a base portion with a shape corresponding to the shape of the central portion 42 and a convex portion with a shape corresponding to the shape of the through-hole 45 (its height is slightly higher than the difference in height between the central portion 42 and the peripheral portion 41 minus the height of the semiconductor package 50). Such a structure enables the semiconductor package 50 to be pressed into the guide 40.

As described above, in the semiconductor socket 100 of this embodiment, the semiconductor package 50, guided mainly by the slope portions 44a, the tapered portions 46a, and the cylindrical portions 46b, and housed in the space surrounded by the side portions 44b, can be positioned in the through-hole 45 without three-dimensional displacement. Therefore, if the stoppers 74 of the push plate 70 are locked by the stopper receivers 47 of the guide 40, the semiconductor package 50 can be positioned in the through-hole 45 while being pressed therein.

### Embodiment 2

FIG. 5(a) and 5(b) are perspective views showing the relationship between a guide 40 and a base 80 attached thereto in a semiconductor socket 100 according to Embodiment 2 of the present invention, wherein FIG. 5(a) shows a perspective view from the surface side and FIG. 5(b) shows a perspective view from the rear side. It should be noted that FIG. 5(a) and 5(b) also show a semiconductor package 50.

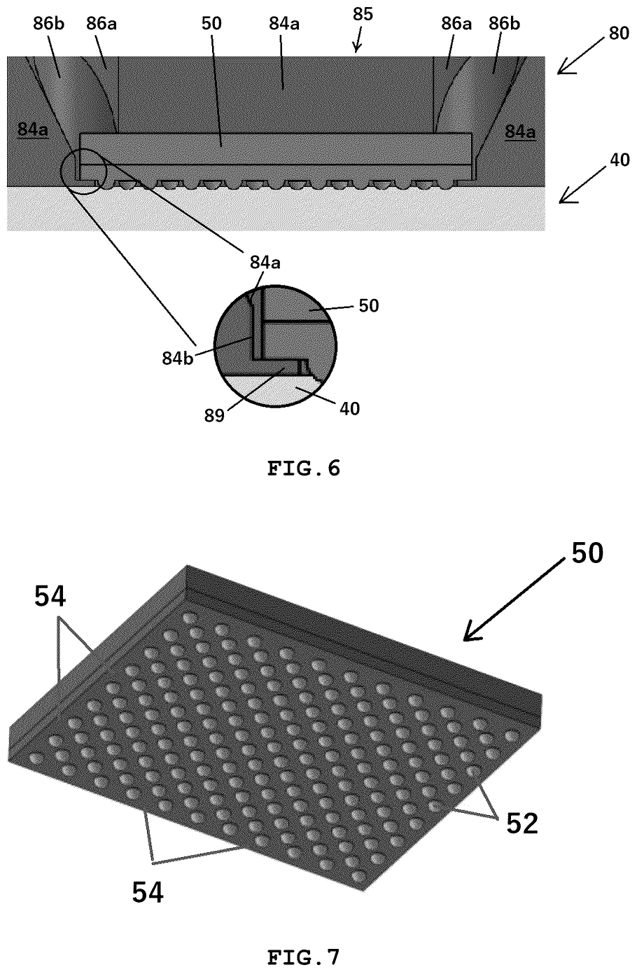

FIG. 6 is a cross-sectional view and a partially enlarged view corresponding to FIG. 5(a) and 5(b), and corresponds to FIG. 4. The base 80 is provided with a through-hole 85 corresponding to the through-hole 45, slope portions 84a corresponding to the slope portions 44a, tapered portions 86a corresponding to the tapered portions 46a, side portions 84b corresponding to the side portions 44b, cylindrical portions 86b corresponding to the cylindrical portions 46b, and a package receiving portion 89 for receiving the rear surface outer edge portion of the semiconductor package 50.

It should be noted that the semiconductor socket 100 of this embodiment may use the members shown in FIG. 1 other than the guide 40. Incidentally, it should be noted that if the size of the semiconductor package 50 to be accommodated is the same as in Embodiment 1, the guide 40 needs to be designed in consideration of the securing of the attachment location for the base 80.

FIG. 7 is a rear perspective view of the semiconductor package 50 shown in FIG. 6. As shown in FIG. 7, on the rear surface of the semiconductor package 50, solder balls 52 as contacts are arranged, for example, in a staggered manner in a region excluding the rear surface outer edge portion 54.

The semiconductor socket 100 of this embodiment, like the semiconductor socket 100 described in Embodiment 1, houses the semiconductor package 50 guided mainly by the slope portions 84a, the tapered portions 86a, and the cylindrical portions 86b into a space surrounded by the side portions 84b and the cylindrical portions 86b. However, unlike the semiconductor socket 100 described in Embodiment 1, in the semiconductor socket 100 of this embodiment, the rear surface outer edge portion 54 is received by the package receiving portion 89.

When accommodating the semiconductor package 50 into the guide 40, the semiconductor socket 100 of this embodiment enables simple alignment by arranging the outer edge of the solder ball arrangement region inside the package receiving portion 89.

### Embodiment 3

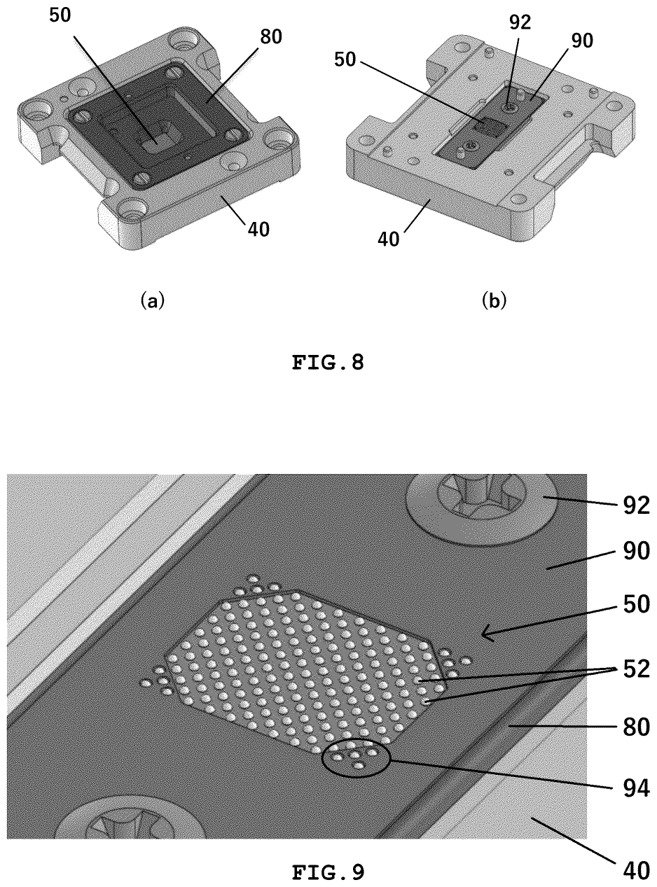

FIG. 8(a) and 8(b) are perspective views showing the relationship between a guide 40 and a base 80 attached thereto in a semiconductor socket 100 according to Embodiment 3 of the present invention and correspond to FIG. 5(a) and 5(b).

FIG. 9 is an enlarged view of the vicinity of the semiconductor package 50 shown in FIG. 8(b). First, as shown in FIG. 8(b), in the semiconductor socket 100 of this embodiment, a package receiving sheet 90 made of a material such as polyimide covers the base 80 on the rear surface of the guide 40 and is attached to the guide 40 by screws 92, and accordingly, an attachment location for the package receiving sheet 90 is secured on the rear surface of the guide 40, which is a point of difference from the semiconductor socket 100 of Embodiment 2.

As shown in FIG. 9, in the package receiving sheet 90, the opposing region of the semiconductor package 50 is opened except for the corner portions with through-holes 94. In the through-holes of the corner portions with through-holes 94, the solder balls 52 located at the rear surface corners of the semiconductor package 50 are positioned. Accordingly, these solder balls 52 can contact the corresponding contacts of the sheet-shaped contacts 34.

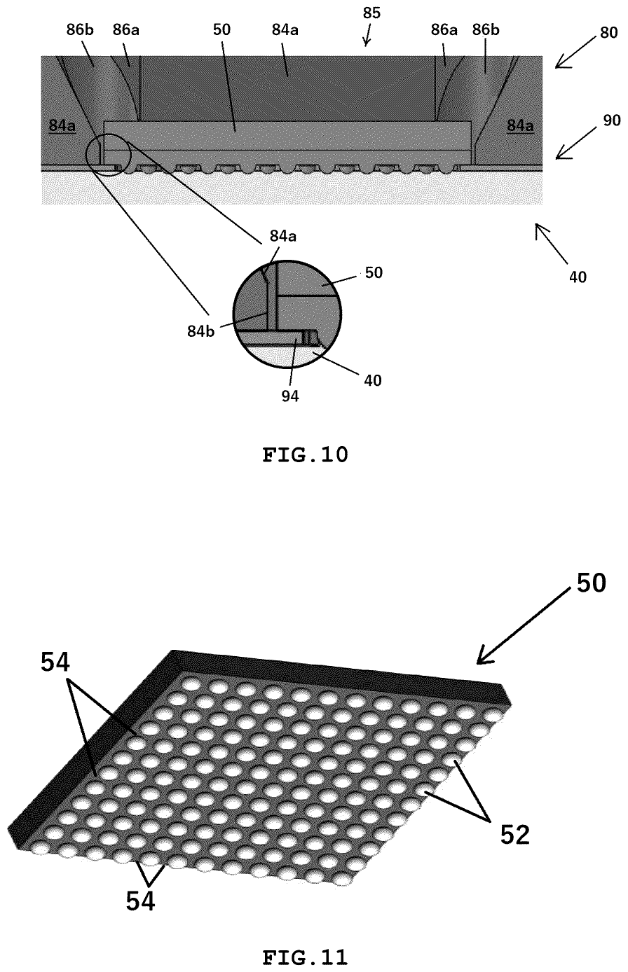

FIG. 10 is a cross-sectional view and a partially enlarged view corresponding to FIG. 8(a) and 8(b) and corresponds to FIG. 6. The base 80 is provided with slope portions 84a, side portions 84b, tapered portions 86a, and cylindrical portions 86b but is not provided with a package receiving portion 89. The role of the package receiving portion 89 is fulfilled by the package receiving sheet 90. It should be noted that, in this embodiment also, the members other than the guide 40 may be those shown in FIG. 1.

FIG. 11 is a rear perspective view of the semiconductor package 50 shown in FIG. 10 and corresponds to FIG. 7. On the rear surface of the semiconductor package 50, solder balls 52 as contacts are arranged, for example, in a staggered manner over the entire surface including the rear surface outer edge portion 54.

The reason why the package receiving sheet 90 is used in place of the package receiving portion 89 of Embodiment 2 in this embodiment is that, as shown in FIG. 11, solder balls 52 are also arranged on the rear surface outer edge portion 54.

That is, in the semiconductor socket 100 of this embodiment, like the semiconductor socket 100 described in Embodiment 2, the semiconductor package 50 is guided by the slope portions 84a, the tapered portions 86a, and the cylindrical portions 86b and housed in the space surrounded by the side portions 84b and the cylindrical portions 86 b but if the guide 40 of Embodiment 2 is used, the width of the package receiving portion 89 must be relatively narrowed. However, since this may make it impossible to reliably receive the semiconductor package 50, in this embodiment, such rear surface corner portions of the semiconductor package 50 are received by the corner portions with through-holes 94 of the package receiving sheet 90.

In the semiconductor socket 100 of this embodiment, if the corner portions with through-holes 94 are designed in accordance with the arrangement mode of the solder balls 52, simple alignment can be achieved as in the case of the semiconductor socket 100 of Embodiment 2.

As described above, the semiconductor sockets 100 of the respective embodiments of the present invention, when summarized, all have the feature that the semiconductor package 50, guided by the slope portions 44a, the tapered portions 86a, and the cylindrical portions 86b and housed in the space surrounded by the side portions 84b and the cylindrical portions 86b, can be positioned within the through-hole 45 without three-dimensional displacement.

Thus, the semiconductor socket 100 of Embodiment 1 has the advantage of being inexpensive compared to the semiconductor sockets 100 of Embodiments 2 and 3, since it does not require components such as the base 80 or the package receiving sheet 90.

The semiconductor sockets 100 of Embodiments 2 and 3, although requiring components such as the base 80 and the package receiving sheet 90, have the advantage that simple alignment of the semiconductor package 50 with respect to the guide 40 can be achieved.

### INDEX TO THE REFERENCE NUMERALS

10 bolster
12 female screw
20 printed circuit board (PCB)
22 resist-formed region
24 resist-free region
25 electrode pad
26 screw hole
30 contact unit
32 positioning sheet
34 sheet-shaped contact
40 guide
41 peripheral portion
42 central portion
43 pin receiver
44a slope portion
44b side portion
45 through-hole
46a tapered portion
46b cylindrical portion
47 stopper receiver
48 screw hole
50 semiconductor package
52 solder ball
54 rear surface outer edge portion
60 male screw
70 push plate
72 positioning pin
74 stopper
80 base
84a slope portion
84b side portion
86a tapered portion
84b cylindrical portion
89 package receiving portion
90 package receiving sheet
92 screw
94 corner portion with through-hole
100 semiconductor socket

1. A semiconductor socket, for positioning each contact arranged in a semiconductor package in a rectangular parallelepiped shape and each corresponding contact piece arranged in a state of being electrically insulated from each other, comprising:
a through-hole including a guide portion for guiding the semiconductor package into a guide body from an arrangement surface of each contact arranged in the semiconductor package and a housing portion for accommodating the semiconductor package guided by the guide portion,
wherein the guide portion includes a tapered portion that faces each edge portion of the arrangement surface and becomes narrower toward a guiding direction of the semiconductor package and a clearance portion that faces each corner portion of the arrangement surface.

2. The semiconductor socket according to claim 1,
wherein the through-hole is formed in a guide located between a contact unit having the respective contact pieces and a push plate that presses the semiconductor package against the contact unit.

3. The semiconductor socket according to claim 1,
wherein the through-hole is formed in a base attached to a guide located between a contact unit having the respective contact pieces and a push plate that presses the semiconductor package against the contact unit.

4. The semiconductor socket according to claim 1,
wherein a receiving portion of the arrangement surface is formed in the through-hole.

5. The semiconductor socket according to claim 1, further comprising:
a package receiving sheet covering the through-hole,
wherein a receiving portion for receiving the arrangement surface is formed in the package receiving sheet.
